(19) United States
(12) Patent Application Publication
(10) Pub. No.: US 2016/0056307 A1
(43) Pub. Date: Feb. 25, 2016

(54) SOLAR CELLS AND MODULES INCLUDING CONDUCTIVE TAPES AND METHODS OF MAKING AND USING THE SAME

(71) Applicant: 3M INNOVATIVE PROPERTIES COMPANY, Saint Paul, MN (US)

(72) Inventors: NELSON T. ROTTO, WOODBURY, MN (US); GREGORY L. BLUEM, SAINT PAUL, MN (US); MARK J. VOTAVA, STILLWATER, MN (US); GUOPING MAO, WOODBURY, MN (US); MARK K. NESTEGARD, LONG LAKE, MN (US); DAVID V. MAHONEY, AUSTIN, TX (US); THOMAS A. STROZ, CASTLE ROCK, CO (US); DMITRIY SALNIKOV, WOODBURY, MN (US)

(21) Appl. No.: 14/778,622

(22) PCT Filed: Mar. 5, 2014
(86) PCT No.: PCT/US14/20518

§ 371 Date: Sep. 21, 2015

Related U.S. Application Data
(60) Provisional application No. 61/804,359, filed on Mar. 22, 2013.
(60) Provisional application No. 61/893,251, filed on Oct. 20, 2013.
(60) Provisional application No. 61/893,634, filed on Oct. 21, 2013.

(51) Int. Cl. H01L 31/02; C09J 7/02

(52) U.S. Cl. CPC H01L 31/0201; C09J 7/0292; C09J 2463/00; C09J 2433/00; C09J 2203/33; C09J 2400/163

(57) ABSTRACT

The inventors of the present disclosure recognized that elimination or reduction of the silver paste and/or silver busbars on the front and/or rear surfaces of solar cells and solar modules would advantageously lower the total cost of the solar cell and/or solar module. The inventors of the present disclosure recognized that the silver paste on the front and rear surface of solar cells or solar modules can be eliminated or the amount of silver paste reduced by replacing the silver busbars with a solderable tape including a conductive metal foil and a nonconductive adhesive.

### CROSS-REFERENCE TO PRIORITY APPLICATIONS

The present application claims priority from U.S. Provisional Application No. 61/804,359, filed on Mar. 22, 2013, U.S. Provisional Application No. 61/893,251, filed on Oct. 20, 2013, and U.S. Provisional Application No. 61/893,634, filed on Oct. 21, 2013. All three provisional applications are incorporated herein by reference.

### TECHNICAL FIELD

The present disclosure generally relates to charge collection tapes and methods of making and using charge collection tapes. The present disclosure also generally relates to crystalline silicon solar cells and modules including charge collection tapes and methods of making and using these cells and modules.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources.

One of the promising energy resources today is sunlight. Globally, millions of households currently obtain power from solar energy generation. The rising demand for solar power has been accompanied by a rising demand for devices and materials capable of fulfilling the requirements for these applications. Solar cells and photovoltaic modules are a fast-growing segment of solar power generation.

Photovoltaic modules convert energy emitted by the sun into electricity. Many photovoltaic modules have a transparent material (e.g., a sheet of glass) on the front (i.e., facing the sun) side. Sunlight passes through the transparent material and is incident on the solar cells. The photons in the sunlight are absorbed by one or more semiconducting material(s) (e.g., multi or mono crystalline silicon) in the solar cells. As photons are absorbed, electrons are knocked loose from their atoms, creating an electric potential difference. The electrons move via diffusion from a region of high electron concentration (the n-type side of the junction) to a region of low electron concentration (the p-type side of the junction), thereby causing current to flow through the semiconductive material. The rear surface of the photovoltaic module typically includes a conductive aluminum material (e.g., fired paste), which acts as an excellent p-type side of the junction.

One exemplary photovoltaic cell is shown schematically in FIGS. 1A, 1B, and 1C. FIGS. 1A and 1B are, respectively, top and bottom schematic views of photovoltaic cell 100. FIG. 1C is a cross-sectional view of photovoltaic cell 100 taken between and parallel to gridlines 122. Photovoltaic cell 100 includes busbars 110a on the front major surface 120 of semiconductor 125 and busbars 110b on the rear major surface 130 of semiconductor 125. Busbars 110a and 110b are thin strips of a highly conductive metal (typically silver) that conduct the direct current that the solar cell(s) collects to a solar inverter, which converts the direct current into useable alternating current. Silver busbars 110a and 110b are solderable. Rear major surface 130 also includes a metalized layer or coating 135 (typically aluminum) on the portion of rear major surface 130 that does not include busbars 110b. Metalized layer or coating 135 forms the p-type side of the semiconductor junction.

Because a single solar cell can produce only a limited amount of power, solar cells are typically grouped together and sold as a photovoltaic module. A photovoltaic module (also referred to as a solar module, a photovoltaic module, a solar panel, or a photovoltaic panel) is a packaged, connected assembly including numerous photovoltaic cells. FIG. 2 is a cross-sectional schematic view of two photovoltaic cells of the type generally shown in FIGS. 1A-1C connected together. The cross-section of FIG. 2 is taken along the length of one set of aligned busbars 110a and 110b. In FIG. 2, two directly adjacent solar cells (first solar cell 150 and second solar cell 155) are connected by a stringing ribbon 160. One portion (e.g., end) of stringing ribbon 160 is soldered directly to busbar 110a on front major surface 120 of first solar cell 150. In some embodiments not shown herein, stringing ribbon 160 is soldered directly to front major surface 120 of first solar cell 150. A second portion (e.g., end) of stringing ribbon 160 is soldered to a busbar 110b on rear major surface 130 of second solar cell 155. Because the metalized coating 135 on rear major surface 130 is not solderable, stringing ribbon 160 cannot be soldered directly to rear major surface 130.

Silver is quite expensive. In fact, the silver busbars represents a significant percentage of the total material costs for c-Si solar cells. Reduction in solar module cost is one of the major targets for cost reduction and areas of solar-related technical innovation over the coming years.

### SUMMARY

The inventors of the present disclosure recognized that elimination or reduction of the front and rear silver busbars on solar cells and solar modules would advantageously lower the total cost of the solar cell and/or solar module. With elimination of the front and rear silver busbars on solar cells, the fine gridlines (or fingers) on the solar cell's frontside are the only remaining structure on the solar cell that utilizes expensive silver paste.

The inventors of the present disclosure recognized that the silver busbars (or silver paste) on the front and rear surface of solar cells or solar modules can be eliminated or reduced by replacing the silver busbars on the front and rear surface with a solderable tape including a conductive metal foil and a nonconductive adhesive. Conductive foils of this type have never been used for this purpose. The inventors of the present disclosure recognized that a tape including a conductive metal foil and a nonconductive adhesive can be applied to the front and rear surface of a solar cell or solar module to provide an electrically conductive surface to which a stringing ribbon can be soldered.

More specifically, some embodiments of the present disclosure relate to a tape for use in a photovoltaic solar cell, the photovoltaic solar cell including a busbar, a rear surface including a conductive metal layer, and a front surface, the tape comprising: a conductive metal foil; and a nonconductive adhesive; wherein at least a portion of the tape is adjacent to either the front or rear surfaces, or both, of the photovoltaic solar cell.

Some embodiments of the present disclosure relate to a method of applying a tape to a photovoltaic solar cell, comprising: (1) obtaining a tape including: a conductive metal foil; and a nonconductive adhesive; (2) applying the tape to either the front or rear surfaces, or both, of the photovoltaic solar cell, with the tape on the back surface in the same relative position as the tape on the front surface so that both the front-side and the back-side tapes can be joined together by a stringing ribbon; and (3) hot pressing the tape and the photovoltaic solar cell.

Some embodiments of the present disclosure relate to a photovoltaic module including a plurality of photovoltaic solar cells at least some of which include a transparent front surface, at least one busbar, a rear surface including a conductive metal layer, and a front surface. The photovoltaic modules further comprising: a solderable tape adjacent to the front and rear surfaces of one or more of the photovoltaic solar cells with the tape on the back surface in the same relative position as the tape on the front surface so that both the front-side and the back-side tapes can be joined together by a stringing ribbon, wherein the tape comprises a conductive metal foil and a nonconductive adhesive.

In some embodiments, the rear surface of the photovoltaic solar cell includes pores and wherein at least some of the nonconductive adhesive enters the pores and enables the conductive metal foil to establish permanent electrical contact to the photovoltaic solar cell. In some embodiments, the nonconductive adhesive enters the pores during hot pressing. In some embodiments, the tape is embossed. In some embodiments, the tape is not embossed. In some embodiments, the conductive metal layer includes at least one of copper, aluminum, tin, iron, nickel, silver, gold, lead, zinc, cobalt, chromium, titanium, and the like. In some embodiments, the tape is solderable. In some embodiments, the nonconductive adhesive is a thermoset adhesive. In some embodiments, the nonconductive adhesive is tacky. In some embodiments, the tape is substantially vertically aligned with the at least one busbar when the tape is adjacent to the photovoltaic solar cell. In some embodiments, the nonconductive adhesive includes epoxy resins, acrylic resins, polyurethanes, polyesters, polyimides, polyamides, cyanate esters, phenolic resins, maleimide resins, phenoxy resins, and the like.

Some embodiments of the present disclosure relates to a tape as described herein.

Some embodiments of the present disclosure relates to a solar cell as described herein.

Some embodiments of the present disclosure relates to a photovoltaic module as described herein.

### BRIEF DESCRIPTION OF DRAWINGS

The disclosure may be more completely understood in consideration of the following detailed description of various embodiments of the disclosure in connection with the accompanying drawings, in which:

FIGS. 1A-1C are schematic diagrams of one exemplary prior art photovoltaic solar cell construction. FIGS. 1A and 1B are, respectively, top and bottom view schematic diagrams of a prior art photovoltaic solar cell construction. FIG. 1C is a cross-sectional view of the photovoltaic solar cell of FIGS. 1A and 1B taken between and parallel to the gridlines.

FIG. 2 is a cross-sectional schematic view of two, connected photovoltaic cells of the type generally shown in FIGS. 1A-1C taken along the length of one set of busbars 110a and 110b.

FIGS. 3A-3C are schematic diagrams of one exemplary photovoltaic solar cell construction consistent with the teachings herein. FIGS. 3A and 3B are, respectively, top and bottom view schematic diagrams of a photovoltaic solar cell construction consistent with the teachings herein. FIG. 3C is a cross-sectional view of the photovoltaic solar cell of FIGS. 3A and 3B taken between and parallel to the gridlines.

FIG. 4 is a cross-sectional schematic view of two, connected photovoltaic cells of the type generally shown in FIGS. 3A-3C taken along the length of the busbars.

FIG. 5 is a cross-sectional view of a tape consistent with the teachings herein.

FIG. 6 is a drawing schematically showing the process of hot pressing an exemplary embossed conductive tape as shown in FIG. 5 to the rear surface of a semiconductor, resulting in the adhesive flowing into the pores of the aluminum coating.

FIG. 7 is a graphical representation of the first Aging test using a temperature cycle.

FIG. 8 is a graphical representation of the fill factor for two different two-cell modules.

FIG. 9 shows an example of a busbar tape of the present disclosure (horizontal elongated rectangular bar) placed on the front side of a photovoltaic cell. The white horizontal lines are the front silver gridlines (fingers).

FIG. 10 is a graphical representation of the fill factor for two different two-cell modules.

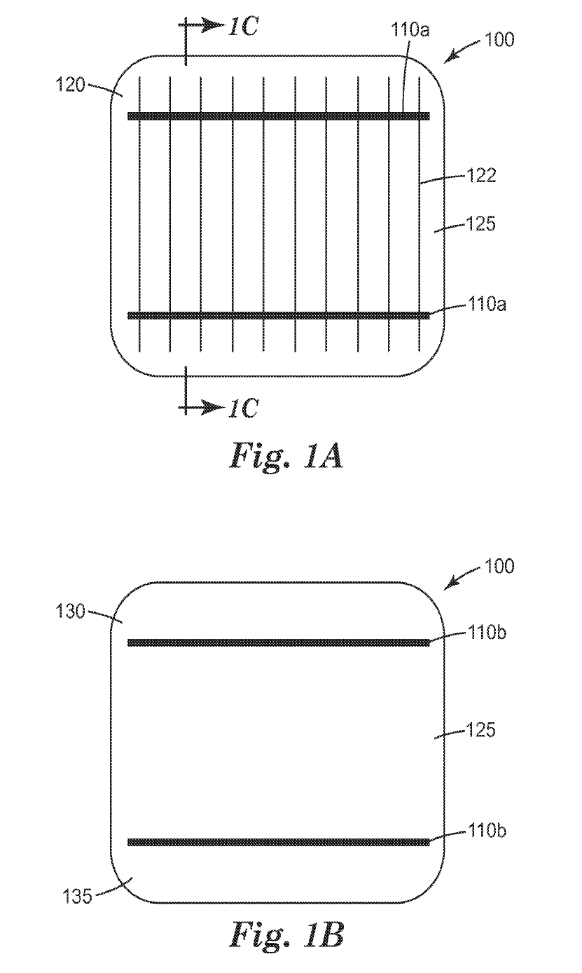

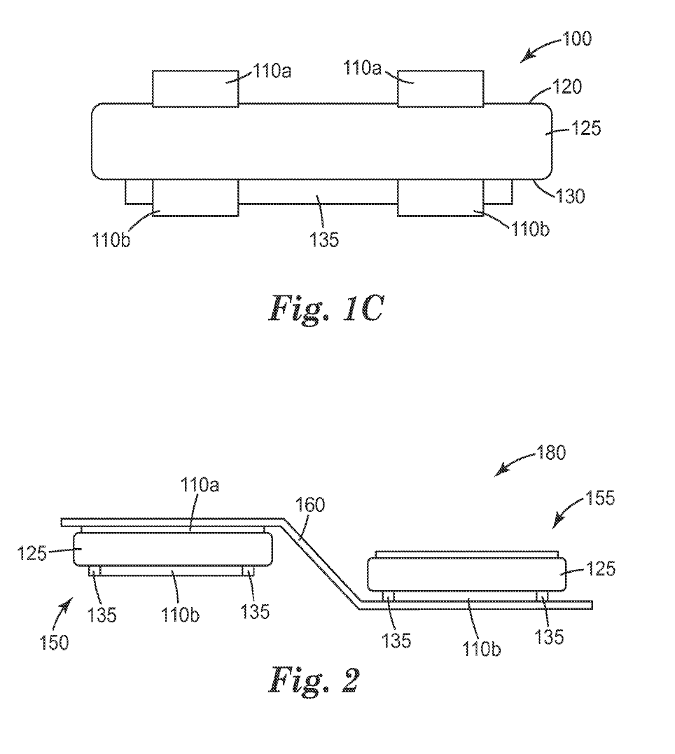

### DETAILED DESCRIPTION

In the following detailed description, reference may be made to the accompanying drawings that forms a part hereof and in which is shown by way of illustration exemplary embodiments. It is to be understood that other embodiments are contemplated and may be made without departing from the scope or spirit of the present disclosure. Any reference to a tape or busbar in the following description is intended to apply to, or refer to, both a front-side tape or a back-side tape according to this disclosure, unless it is otherwise explicitly specified or unless it is clear from the context that the description refers to only a back-side tape or a front-side tape.

The present disclosure generally relates to ways to reduce the cost of a solar cell and/or a solar module by reducing or eliminating the silver or silver busbars in the solar cell or solar module. In some embodiments, the present disclosure generally relates to the use of a tape including a conductive metal foil and a nonconductive adhesive on the front and rear surface of a solar cell to provide an electrically conductive surface to which a stringing ribbon can be soldered.

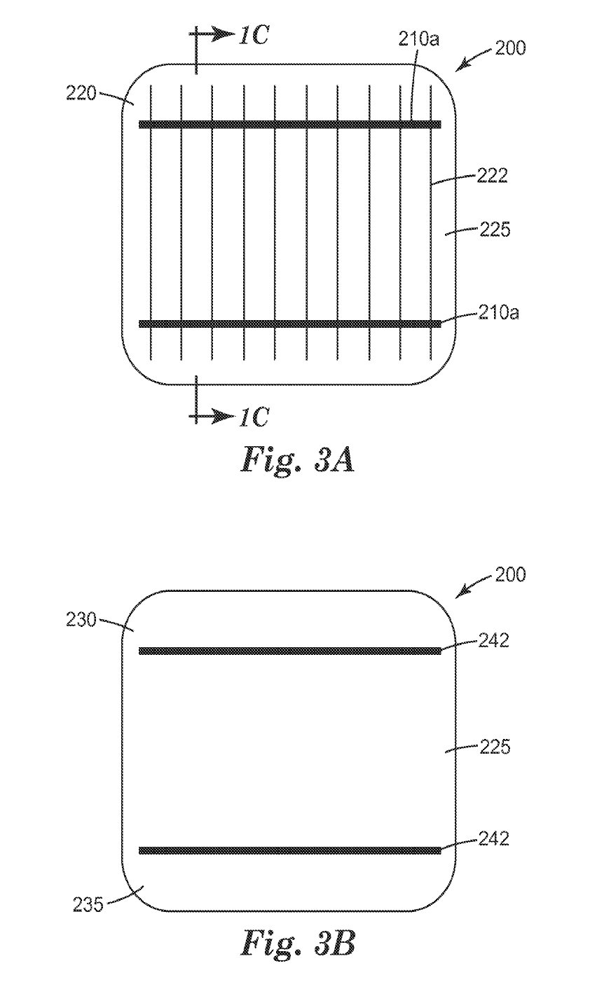

One exemplary embodiment of the present disclosure is shown schematically in FIGS. 3A-3C. FIGS. 3A and 3B are, respectively, top and bottom schematic views of photovoltaic cell 200. FIG. 3C is a cross-sectional view of photovoltaic cell 200 taken between and parallel to gridlines 222. In these figures, photovoltaic cell 200 includes busbars according to this disclosure 210a and gridlines 222 on the front major surface 220 of semiconductor 225. In some embodiments (including the exemplary embodiment shown in FIGS. 3B-3C), the entire rear surface 230 of solar cell 200 includes a conductive aluminum material 235 (e.g., fired paste), which acts as an excellent p-type side of the semiconductive junction. In other embodiments, only one or more portions of rear surface 230 of solar cell 200 include conductive aluminum material 235 (e.g., fired paste). One or more pieces of conductive tape 242 are adjacent (either directly adjacent or indirectly adjacent such that other layers are between) rear surface 230 of semiconductor 225.

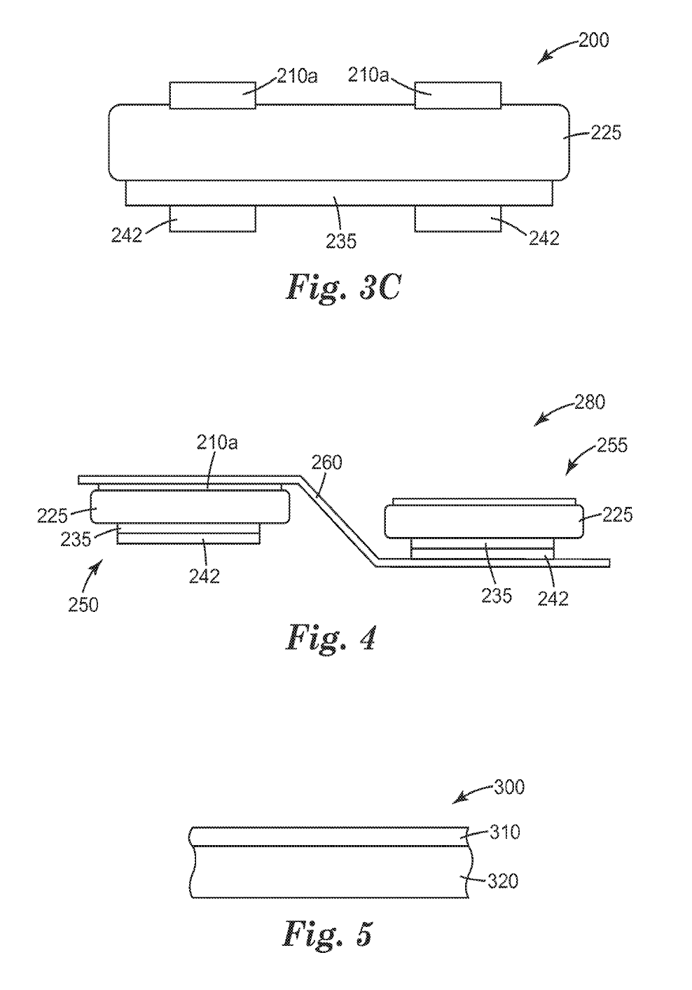

FIG. 4 shows a schematic cross-sectional view of a portion of a photovoltaic module 280 in which two directly adjacent solar cells (first solar cell 250 and second solar cell 255) are connected by a stringing ribbon 260. One portion (e.g., end) of stringing ribbon 260 is soldered directly to busbar according to this disclosure 210a on front major surface 220 of first solar cell 250. A second portion (e.g., end) of stringing ribbon 260 is soldered to conductive tape 242 on rear major surface 230 of second solar cell 255. In the exemplary embodiment shown in FIG. 4, stringing ribbon 260 is soldered directly to conductive tape 242.

The conductive tapes that can be used in solar cells and solar modules to replace or reduce the use of silver paste can be of any type that would permit the stringing ribbon to be soldered to the solar cell. The tapes can be embossed or non-embossed. The tapes may have any desired thickness and tackiness.

FIG. 5 is a cross-sectional schematic diagram of an exemplary embodiment of a conductive tape that can be used in solar cell or photovoltaic module as described herein. In general, conductive tapes for use in the present disclosure include one or more conductive metal foils and at least one layer of nonconductive adhesive. In the specific embodiment shown in FIG. 5, conductive tape 300 includes a metal foil 310 and a nonconductive adhesive 320. The tape may include additional layers. Some exemplary additional layers include flux layers, light-redirecting layers, anti-corrosion layers, removable protective layers, and the like. In some embodiments, the conductive tape 300 can include a metal foil with multiple layers.

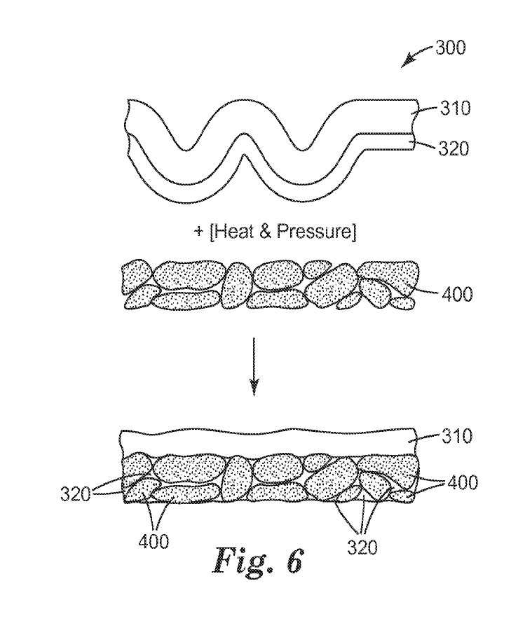

FIG. 6 is a drawing schematically showing the process of hot pressing an exemplary embossed conductive tape as described herein (and one example of which is schematically shown in FIG. 5) to a porous aluminum coating on the rear surface of a semiconductor. As shown in FIG. 6, the conductive tape of FIG. 5 is hot pressed (subjected to heat and pressure and pressed against) porous conductive aluminum material 400 (the coating on the rear surface of a semiconductor, not shown). The resulting construction forms an electrical contact by means of portions of the nonconductive adhesive 320 filling the pores in porous conductive aluminum material 400. Also, metal foil 310 conforms to the surface of and makes electrical contact with porous conductive aluminum material 400 while being locked into place by the curing of the nonconductive adhesive underneath. Although FIG. 6 shows embossed conductive tape, non-embossed conductive tape can also be used.

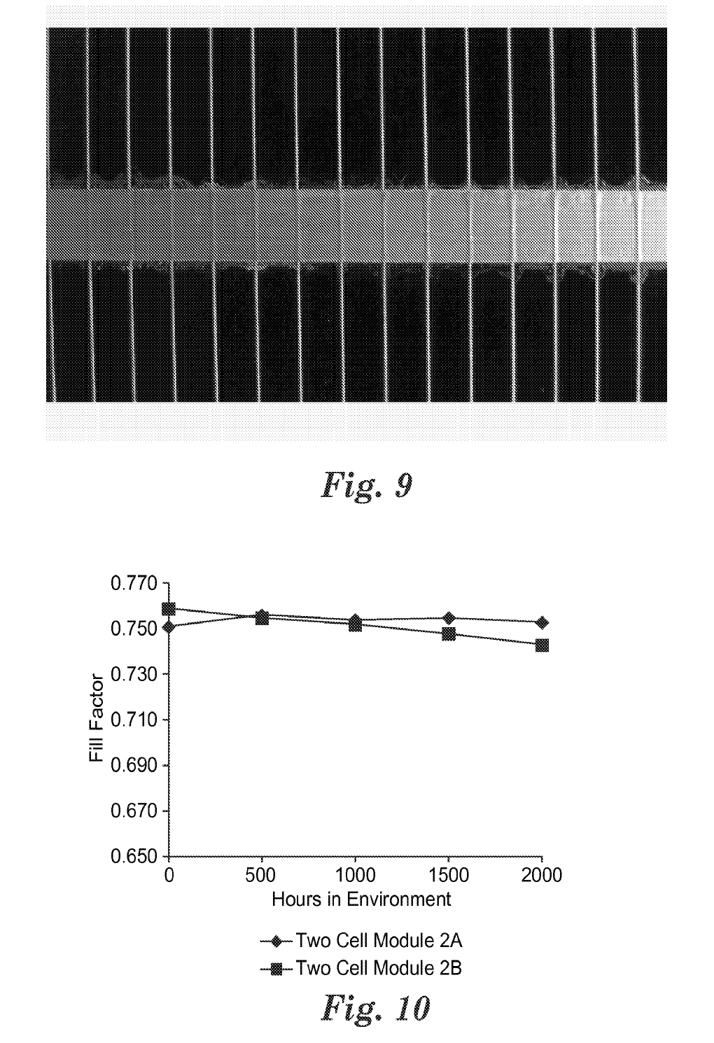

FIG. 9 shows a busbar tape of the present disclosure (vertical elongated rectangular bar) wrapping around the fine silver gridlines on the front side of a photovoltaic cell. The conductive tape of FIG. 5 is hot pressed (subjected to heat and pressure and pressed against) the front surface of a photovoltaic cell. The resulting construction forms an electrical contact with the fine silver gridlines by the metal foil 310 conforming to the surface of the cell and wrapping itself around the silver gridlines. The busbar on the front-side can be formed by embossed conductive tape or non-embossed conductive tape.

Any metal foil may be used in the tape of the present disclosure. Exemplary metal foil materials include, for example, copper, aluminum, tin, iron, nickel, silver, gold, lead, zinc, cobalt, chromium, titanium, and the like. The metal foil layers may be of any desired thickness. Some embodiments have a metal foil layer thickness that is between about 5 microns and about 35 microns. Some embodiments have a metal foil layer thickness that is between about 5 microns and about 20 microns. Some embodiments have a metal foil layer thickness that is between about 5 microns and about 15 microns. In some embodiments, the thickness of the tape is 5 microns, or 6 microns, or 7 microns, or 8 microns, or 9 microns, or 10 microns, 11 microns, or 12 microns, or 13 microns, 14 microns, or 15 microns. In some embodiments, the metal foil thickness is any thickness that does not cause an unacceptable level or bowing or warping of the solar cell or that does not create an unacceptable electrical contact with the silver gridlines. Some embodiments of the conductive tapes and solar cells described herein exhibit bowing or warping of less than 3 mm. Some embodiments of the conductive tapes and solar cells described herein exhibit bowing or warping of less than 2 mm. Some embodiments of the conductive tapes and solar cells described herein exhibit bowing or warping of less than 1.5 mm.

In certain embodiments of the front-side busbar tape, the tape is sufficiently flexible to conform to the fine silver gridlines on the front side of a photovoltaic cell when bonded under pressure or under hot-pressing conditions. In other embodiments, the front-side busbar tape is capable of adhering to crystal-silicon photovoltaic material, as well as the fine silver gridlines on the front side of a photovoltaic cell and make an electrical connection with those silver gridlines.

The metal foil layers may have any desired amount of electrical conductivity. Some embodiments have a metal foil layer electrical conductivity that is greater than 5×10⁷ S/m at 23° C. Some embodiments have a metal foil layer electrical conductivity that is greater than 1×10⁶ S/m at 20° C.

In certain embodiments, the metal foil comprises a passivated Electro-Deposited (ED) High Temperature Elongation (HTE) Copper foil. In other embodiments, the metal foil comprises a Zn barrier layer to keep the foil from corroding or oxidizing. In some embodiments, the elongation of the copper foil is from 6 to 11%. In other embodiments, the elongation of the copper foil is 6 percent, or 7 percent, or 8 percent, or 9 percent, or 10, percent, or 11 percent, or 12 percent.

In certain embodiments, the tensile strength of the foil tape is from 20 to 40 Kpsi. In other embodiments the tensile strength is from 25 to 35 Kpsi. In some embodiments, the tensile strength is 25 Kpsi, or 26 kpsi, or 27 Kpsi, or 28 kpsi, or 29 Kpsi, or 30 kpsi, or 31 Kpsi, or 32 kpsi, or 33 Kpsi, or 34 kpsi, or 35 Kpsi.

| | Units | Typical Value | Range |
|---|---|---|---|
| Thickness | micro meters | 12 | 5 to 20 |
| Surface roughness | microinches | 200 | 50-500 |
| Elongation | % | 8 | 6 to 11 |
| Tensile Strength | Kpsi | 30 | 26 to 32 |
| Volumetric Resistivity | Ohm m | 1.84*10\hat{ }8 | 10% |

Any nonconductive adhesive may be used in the tape of the present disclosure. In some embodiments, the nonconductive adhesive has a rheology that allows it to penetrate at least some of the pores in the metalized layer on the rear surface of the solar cell during bonding conditions that are greater than ambient heat and pressure. When the nonconductive adhesive enters the pores, it enables the conductive metal foil adjacent to the adhesive to establish permanent electrical contact to the solar cell.

In some embodiments, the nonconductive adhesive has an acceptable room temperature shelf life. As used herein, the term “shelf life” refers to the time period at room temperature over which the adhesive remains tacky enough to allow the tape to remain flat once applied to the rear side of a solar cell and after which the tape is able to endure at least 200 cycles of thermal cycling (−40° C. to 90° C.) and damp heat (85° C./85% Relative Humidity testing) for at least 1000 hours with less than 5% increase in resistance of the electrical connection. In some embodiments of the present disclosure, the room temperature shelf life of the nonconductive adhesive and/or the conductive tape is at least a 3 week shelf life. In some embodiments of the present disclosure, the room temperature shelf life of the nonconductive adhesive and/or the conductive tape is at least a 4 week shelf life. In some embodiments of the present disclosure, the room temperature shelf life of the nonconductive adhesive and/or the conductive tape is at least a 5 week shelf life. In some embodiments of the present disclosure, the room temperature shelf life of the nonconductive adhesive and/or the conductive tape is at least a 6 week shelf life.

Exemplary nonconductive adhesive include epoxy resins, acrylic resins, polyurethanes, polyesters, polyimides, polyamides, cyanate esters, phenolic resins, maleimide resins, phenoxy resins, and the like.

Some embodiments of the nonconductive adhesive include a thermoset adhesive. As used herein, the term “thermoset” refers to a resin which changes irreversibly under the influence of energy from a fusible and soluble material into one that is infusible and insoluble through the formation of a covalently crosslinked, thermally stable network. Exemplary thermoset adhesives include epoxy resins, acrylic resins, polyurethanes, polyesters, cyanate esters, phenolic resins, maleimide resins, and the like.

The nonconductive adhesive layer for either the front-side tape and the back-side tape may be of any desired thickness, and is chosen independently of each other. Some embodiments have a nonconductive adhesive layer thickness that is between about 5 microns and about 50 microns. Some embodiments have a nonconductive adhesive layer thickness that is between about 5 microns and about 30 microns. Some embodiments have a nonconductive adhesive layer thickness that is between about 5 microns and about 20 microns. Some embodiments have a nonconductive adhesive layer thickness that is between about 1 microns and about 20 microns. Some embodiments have a nonconductive adhesive layer thickness that is between about 5 microns and about 15 microns. Some embodiments have a nonconductive adhesive layer thickness that is between about 5 microns and about 15 microns. Some embodiments have a nonconductive adhesive layer thickness that is between about 8 microns and about 13 microns. In some embodiments, the nonconductive adhesive layer thickness is about 1 microns, 2 microns, 3 microns, 4 microns, 5 microns, 6 microns, 7 microns, 8 microns, 9 microns, 10 microns, 11 microns, 12 microns, 13 microns, 14 microns, 15 microns, 16 microns, 17 microns, 18 microns, 19 microns, 20 microns, 21 microns, 22 microns, 23 microns, 24 microns, 25 microns, or 26 microns. In some embodiments, the thickness of the front-side tape adhesive is thinner than the thickness of the back-side tape adhesive.

In its uncured state, the nonconductive adhesive can have any desired tackiness, provided that the adhesive is tacky enough at room temperature to allow the tape to be applied to the rear side of a solar cell at about 0.35 MPa of pressure and subsequently prevent the tape from lifting more than 2 mm at room temperature without the application of any external force

The conductive tapes described herein can be bonded to the rear surface of the solar cell or photovoltaic module using any known method. In some embodiments, the tape is generally aligned with one or more of the front side busbars (either silver busbars in a solar cell that does not use the front-side tape of the present disclosure or the busbars made with the front-side tape of the present disclosure). The alignment of back-side tape with front-side tape is made in such a way that they can be joined together by a stringing ribbon. In some embodiments, the entire solar cell (including the tape) is hot pressed. As used herein, the term “hot pressed” or “hot pressing” refers to a method of heating the adhesive to a temperature greater than about 100° C. and simultaneously applying a pressure of greater than about 0.35 MPa to establish a reliable adhesive bond. Exemplary methods of hot pressing include, for example, hot bar bonding, hot platen-pressing, hot roll-to-roll lamination, hot vacuum lamination, and the like.

In some embodiments, the nonconductive adhesive permits a bonding time of less than 120 seconds. In some embodiments, the nonconductive adhesive permits a bonding time of less than 60 seconds. In some embodiments, the nonconductive adhesive permits a bonding time of less than 20 seconds. In some embodiments, the nonconductive adhesive permits a bonding time of less than 10 seconds.

Some embodiments of the photovoltaic modules, solar cells, and/or conductive tapes of the present disclosure endure one or both of at least 200 cycles of thermal cycling (−40° C. to 90° C.) and damp heat (85° C./85% Relative Humidity testing) for at least 1000 hours with less than 5% increase in resistance of the electrical connection. Some embodiments of the photovoltaic modules, solar cells, and/or conductive tapes of the present disclosure endure one or both of 400 thermal cycles (−40° C. to 90° C.) and damp heat (85° C./85% Relative Humidity testing) for at least 2000 hours with less than 5% increase in resistance of the electrical connection. Some embodiments of the photovoltaic modules, solar cells, and/or conductive tapes of the present disclosure endure one or both of 600 thermal cycles (−40° C. to 90° C.) and damp heat (85° C./85% Relative Humidity testing) for at least 3000 hours with less than 5% increase in resistance of the electrical connection. In one embodiment, the photovoltaic modules, solar cells, and/or conductive tapes of the present disclosure do not contain conductive particles.

The photovoltaic modules, solar cells, and conductive tapes of the present disclosure have many advantages and benefits. Some of these advantages and benefits are described below. Some embodiments of the photovoltaic modules, solar cells, and conductive tapes described herein can maintain function even when subjected to the vacuum and high temperature conditions required for encapsulation of solar cells. Some embodiments of the photovoltaic modules, solar cells, and conductive tapes described herein can maintain function even when subjected to environmental conditions such as damp heat and thermal cycling.

### EXAMPLES

The following examples are intended to illustrate embodiments within the scope of this disclosure. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

Test Methods

Aging Test for Back-Side Tape

Two aging tests were performed. In a first test, single-cell test modules prepared as described in TEST PANEL 1-3, Comparative Test Panels A to H, and Example 7 were placed in an environmental chamber (model “ESZ-4CA”, obtained from ESPEC, Hudsonville, Mich.) set to continuously cycle between temperatures of about −40° C. and 90° C. over a 5 hour period. The modules remained in the environmental chamber for up to 2500 hours.

In a second test, single-cell test modules prepared as described in TEST PANEL 1-3, Comparative Test Panel A, and Example 7 were placed in the environmental chamber (model “ESX-4CA”, obtained from ESPEC, Hudsonville, Mich.) set to a temperature of 85° C. and 85% relative humidity (85° C./85% Relative Humidity testing). The modules remained in the environmental chamber for up to 2500 hours.

Aging Test for Front-Side Tape

Two aging tests were performed. In a first test, two-cell modules prepared as described in TWO-CELL MODULE 1B and 2B were placed in an environmental chamber (model “ESZ-4CA”) programmed to continuously cycle between temperatures of about −40° C. and 90° C. over a 5 hour period. The modules remained in the environmental chamber for up to 2500 hours.

In a second test, two cell modules prepared as described in TWO-CELL MODULE 1A and 2A were placed in the environmental chamber (model “ESX-4CA”) set to a temperature of 85° C. and 85% relative humidity (85° C./85% Relative Humidity testing). The modules remained in the environmental chamber for up to 2500 hours.

Resistance Measurements

Resistance of the metal tape according to the present examples was measured before (initial) and after the aging test. A single cell test module was measured using a four point test, wherein two amps of DC current were put across the parallel strips of the metal tapes with a power supply (model U8002A obtained from Agilent, Santa Clara, Calif.), and the voltage was measured across the opposite ends of the strips with a multimeter (model 34401A obtained from Agilent). The two multimeter probes were placed on the metal strips as close as possible to where the strips exit the test panel. The resistance was then calculated using Ohm's law. After measuring the initial resistance, the panels were placed in the environmental chamber. The resistance was measured periodically by removing the panels from the environmental chamber and measuring the resistance using the above-described procedure.

Photovoltaic Module Testing

Photovoltaic module testing on two-cell modules was done on a Spi-Sun Simulator 3500 SLP Photovoltaic Module Tester manufactured by Spire Corp., in Bedford, Mass. The software for this photovoltaic module tester calculates various values for parameters from the current-voltage curve such as fill factor, open circuit voltage (Voc), short circuit current (Isc), maximum power (Pmax), shunt resistance (Rs), and efficiency. After initial module testing with the photovoltaic module tester, the two-cell modules were placed in environmental chambers and periodically removed for module testing.

### Example 1

A copper foil having a thickness of 12 microns (obtained under the trade designation “TOB-III”, from OakMitsui, Camden, S.C.) was provided. The copper foil had a first surface and a second surface, the first surface being dull. A solvent based epoxy thermoset adhesive was prepared using the ingredients listed in Table 1, below, wherein the amount of each ingredient is expressed as weight percent based on the total adhesive weight. The adhesive was coated onto the dull surface of the copper foil using a laboratory handspread apparatus. The coated copper foil was placed in an oven for 10 minutes at a temperature of about 60° C. to form a metal tape having a dry adhesive layer that was about 20 microns thick. A release liner having a thickness of about 1 mil (25 micron) (obtained under the trade name “T-50”, from Eastman Chemical Co., Martinsville, Va.) was laminated to the adhesive layer. The metal tape was subsequently embossed with a dot pattern using a platen press. The dot pattern in the embossing tool comprised protrusions arranged in a trapezoidal configuration at a density of 41 protrusions per square centimeter. Each protrusion had a height of about 0.39 mm, and diameters of about 0.74 mm at the base and about 0.43 mm at the top. A force of about 12,000 lbs (5443 kgf) was applied to a 6 in by 6 in (15 cm by 15 cm) embossing tool comprising the dot pattern, which was placed over the metal tape. The embossed tape was then slit into 3 mm wide strips.

TABLE 1
Composition of Solvent Based Epoxy
Thermoset Adhesive of Example 1

| | Trade | | Weight |
|---|---|---|---|
| Ingredient | designation | Supplier | percent (%) |
| Epoxy resin | EPON SU-2.5 | Momentive, | 41.13 |
| | | Columbus, OH | |
| Phenoxy resin | PKHP-200 | InChem Corporation, | 5.50 |
| in methyl ethyl | | Rock Hill, SC | |
| ketone | | | |
| Core-shell | PARALOID | Dow Chemical, | 5.50 |
| particles | EXL-2330 | Midland, MI | |
| Epoxy curative | 2MZ-AZINE | Air Products, | 2.87 |
| | (fine grind) | Allentown, PA | |
| Solvent | Methyl | Brenntag Great Lakes, | 45.00 |
| | ethyl ketone | Wauwatosa, WI | |

### Example 2

An 18 micron thick and 14 in (35 cm) wide copper foil (obtained under the trade designation “TOB-HI”, from Oak Mitsui) was coated with the thermoset adhesive described in Example 1. The adhesive was coated onto the dull side of the copper foil using a notch bar (or gap) coating technique, at a line speed of about 10 ft/min (3 m/min). After coating, the coated copper foil passed through three consecutive ovens which heated to temperatures of, respectively, 82° C., 82° C., and 93° C., for a total drying time of about 2 minutes. The thickness of the dried adhesive layer was about 20 microns. A 2 mil release liner (obtained under the trade designation T-50 from Eastman Chemical Co., Martinsville, Va.) was laminated onto the adhesive just prior to winding the metal tape onto a core. In a separate off line operation, the metal tape was embossed by passing it through a roll-to-roll embossing apparatus at a line speed of about 5 ft/min (1.5 m/min). One of the embossing rolls had the metallic dot pattern of Example 1, while the other roll was compliant. A force of 1250 lbs (567 kgf) was used across the 14 inch wide foil tape to achieve the embossed structure. After embossing, the metal tape was slit into 3 mm wide strips.

### Example 3

A metal tape was prepared as described in Example 1, except that the metal tape was not embossed.

### Example 4

A metal tape was prepared as described in Example 1, except that the solvent based adhesive composition was prepared following: ingredients listed in Table 2, below. The ingredients were mixed in the order listed in Table 2, except for the second charge of MEK, which was added as described below. The mixture was mixed aggressively with a cowles-type mixer for 1 hour. The second charge of MEK was then added slowly with mixing, and the resulting mixture was gently mixed for 5 minutes. The mixture was subsequently filtered through a 100 micron filter. The amount of each ingredient in Table 2 is expressed as weight percent based on the total adhesive weight.

TABLE 2
Composition of Solvent Based Epoxy
Thermoset Adhesive of Example 4

| | Trade | | Weight |
|---|---|---|---|
| Ingredient | designation | Supplier | percent (%) |
| Epoxy resin | EPON SU-2.5 | Momentive, | 29.91 |
| | | Columbus | |
| 40% Phenoxy resin | PKHS-40 | InChem | 10.00 |
| in methyl ethyl | | Corporation | |
| ketone | | | |
| Core-shell | PARALOID | Dow Chemical, | 4.00 |
| particles | EXL-2330 | Midland | |
| Epoxy curative | 2MZ-AZINE | Air Products, | 2.09 |
| | (fine grind) | Allentown | |
| Solvent | Methyl ethyl | Brenntag | 6.64 |
| | ketone (MEK) | Great Lakes | |
| | (first charge) | | |
| Solvent | MEK | Brenntag | 47.36 |
| | (second charge) | Great Lakes | |

The adhesive was further filtered through a 30 micron filter and then coated onto the primed side of the 17 inch wide and 12 micron thick copper foil (Oak Mitsui TOB-III). The line speed of the coating process was 60 ft/min. The adhesive layer was dried in a series of drying ovens set, respectively, at 130° F. (54° C.), 150° F. (65° C.), and 170° F. (77° C.). The adhesive layer was subsequently sent through two standard 25 ft (7.6 m) long drying ovens set at 170° F. The dried adhesive layer had a thickness of 20 microns. The release liner was laminated over the adhesive layer, and the 17 in (43 cm) wide metal tape was slit into two 8 in (20 cm) wide rolls.

The two metal tape rolls were embossed as described in Example 1, except that an embossing force of 700 lbf (317 kgf) was applied, and a line speed of 20 ft/min (6 m/min) was used for the embossing process. In addition, an unwind tension of 1 lbf (0.45 kgf) and a wind tension of 20 lbf (54 kgf) were applied. The embossed metal tape was slit into 3 mm wide rolls.

### Comparative Example A

A metal tape was prepared as described in Example 1, except that a solvent-based epoxy thermoset adhesive containing conductive particles was used. The conductive epoxy adhesive was prepared using the ingredients listed in Table 3 below, where the amount of each ingredient is expressed as percent based on the total weight of the adhesive. Using the laboratory handspread apparatus, the conductive epoxy adhesive was coated on the dull side of a 35 micron copper foil (obtained under the trade designation “ML” from OakMitsui). A conductive scrim (obtained under the trade designation “T2554”, from Technical Fibres, Newburgh, N.Y.) was subsequently embedded in the adhesive. The coated metal foil was dried in the 60° C. oven for 12 minutes. A 1.5 mil thick release liner (obtained under the trade name T-10 from Eastman Chemical Co., Martinsville, Va.) was laminated over the adhesive. The metal tape was slit to 3 mm strips.

TABLE 3
Composition of Conductive Epoxy
Adhesive of Comparative Example A

| | Trade | | Weight |
|---|---|---|---|
| Ingredient | designation | Supplier | percent (%) |
| Epoxy resin | EPON SU-2.5 | Momentive | 47.68 |
| Phenoxy resin | PKHP-200 | InChem | 7.34 |
| Coupling | A174 (3- | Sigma Aldrich | 0.37 |
| agent | glycidoxpropyl- | | |
| | trimethoxy silane) | | |
| Core-shell | PARALOID | Dow Chemical | 7.34 |
| particle | EXL-2330 | | |
| Epoxy curative | ARADUR | Huntsman Advanced | 2.86 |
| | XB3123 | Materials, The | |
| | | Woodlands, TX | |
| Epoxy curative | ECAT-243 | Designer Molecules | 0.47 |
| | | Inc, San Diego, CA | |
| Conductive | S3000S3M | Potters Industries | 7.34 |
| silver particle | | Inc, Malvern, PA | |
| Solvent | Methyl | Brenntag | 26.60 |
| | Ethyl Ketone | Great Lakes | |

### Comparative Example B

A charge collection tape commercially available under the trade designation “Charge Collection SOLAR Tape 6013” from 3M Company was obtained and is hereinafter referred to as Comparative Example B. This tape comprised an embossed tin coated copper foil containing a non-conductive pressure sensitive adhesive.

### Comparative Example C

An adhesive tape commercially available under the trade designation “9706 Electrically Conductive Adhesive Transfer Tape” from 3M Company was obtained. In the 9706 tape, the adhesive film is between two release liners. One of the liners is removed to expose the adhesive, which is then laminated to the metal foil producing a structure liner/adhesive/foil. This adhesive tape comprised a pressure-sensitive adhesive containing conducting particles. A metal tape was prepared by laminating a 6 in by 2 in (15.2 cm by 5 cm) piece of tape to the center of a 9 in by 2 in (22.8 cm by 5 cm) piece of 12 micron copper foil (Oak Mitsui TOB-III). Lamination was carried out at room temperature with the adhesive contacting the dull/primed side of the copper foil. Lamination was conducted using a rubber roller at a pressure of about 7 pounds of force. The resulting laminate was slit into 3 mm by 9 inch strips.

### Comparative Example D

A metal tape was prepared as described in Comparative Example C, except that the adhesive tape was obtained under the trade designation “9707 Electrically Conductive Adhesive Transfer Tape” from 3M Company. This adhesive tape comprised a pressure-sensitive adhesive containing conductive particles.

### Comparative Example E

A metal tape was prepared by laminating an adhesive tape commercially available under the trade designation “Anisotropic Conductive Film 7373” from 3M Company to 3 mm wide strips of the 12 micron copper foil. This adhesive tape comprised a thermoset adhesive film containing conductive particles. Lamination was conducted using a rubber roller at room temperature and a pressure of about 7 pounds of force.

### Comparative Example F

A metal tape was prepared as described in Comparative Example E, except that a tape commercially available under the trade designation “Anisotropic Conductive Film 7303” from 3M Company was used. This adhesive tape comprised a thermoset adhesive film containing conductive particles.

### Comparative Example G

A metal tape was prepared as described in Comparative Example E, except that a tape commercially available under the trade designation “Anisotropic Conductive Film 7378” from 3M Company was used. This adhesive tape comprised a thermoset adhesive film containing conductive particles. The copper foil and adhesive were 4 mm wide, and lamination was carried out on a surface heated to approximately 80° C. with a rubber roller using approximately 7 lbs of force.

### Comparative Example H

A metal tape was prepared as described in Comparative Example E, except that a tape commercially available under the trade designation “Anisotropic Conductive Film 7376-30” from 3M Company was used. This adhesive tape comprised a thermoset adhesive film containing conductive particles. Lamination was carried out on a surface heated to approximately 80° C. with a rubber roller using approximately 7 lbs of force.

Test Panel 1

A test panel was prepared in order to test various electrical properties. The test panel was prepared by adhering two metal tape strips prepared as described in Example 1 above to the aluminum backside of a standard crystalline silicon solar cell (obtained under the trade designation “ARTISUN SELECT MONOCRYSTALLINE CELL” (18.60-18.80% efficiency) from Suniva Co, Norcross, Ga.). The two metal tape strips were placed approximately 42 mm apart, between and parallel to two backside silver busbars. The metal tape strips extended approximately 25 mm in lengthwise direction beyond each edge of the solar cell. The exposed adhesive layer on the extended portions of the metal tape was removed with MEK solvent. A hot bar bonder (obtained under the trade designation “CHERUSAL”, from Trimech Technology, Singapore) was used to impart pressure and heat to the metal tape. The hot bar (thermode strip) was 150 mm long and 3 mm wide. The bonding process was done at a constant pressure of 200 psi over 10 seconds. A thin piece of silicone rubber interposer (supplied by Trimech Technology) was placed between the metal tape and the hot bar. The temperature of the hot bar was controlled over this 10 second bonding period, using the following heating profile: ramp to 350° C. over 1 second; hold at 350° C. for 3 seconds; ramp to 320° C. over 3 seconds; hold at 320° C. for 1 second; ramp to 300° C. over 1 second; and hold at 300° C. for 1 second. After the bonding process, the tip of a soldering iron heated to a temperature of 350° C. was placed in contact with the bonded metal tape and moved across the entire length of the bonded metal tape over a 5 second period of time to simulate an actual soldering process.

A test panel was prepared by placing the following components in a laminator (model “LM-50X50-S”, obtained from NPC, Tokyo, Japan): an ethyl vinyl acetate (EVA) encapsulant (obtained under the trade designation “3M 9000”, from 3M Company, St. Paul, Minn.) was disposed on the front side of the solar cell prepared as described above, and an 8 in by 8 in soda lime float glass (⅛ in thick (0.31 cm)) (obtained from Brim Northwestern, Minneapolis, Minn.) was disposed over the EVA encapsulant. A backsheet (obtained from 3M Company under the trade designation “SCOTCHSHIELD FILM 15T”) was disposed adjacent the back side of the solar cell. Lamination of these layers was carried out using the following process conditions: a 4 min pump down at 150° C. (with the pins up) followed by a 12 minute press at 150° C. The resulting test panel comprised two 3 mm wide metal tape strips, each extending approximately 25 mm beyond each lengthwise edge of the module, for a total of four contact leads. These four contact leads were used in the four point test to determine contact resistance, as described above.

Test Panel 2

Test Panel 2 was prepared as described in Test Panel 1, except that the metal tape used in the cell was prepared as described in Example 2.

Test Panel 3

Test Panel 3 was prepared as described in Test Panel 1, except that the metal tape used in the cell was prepared as described in Example 3.

Two-Cell Module 1

Three strips of the metal tape of Example 4 were applied to an aluminum backside of a crystalline silicon solar cell (4.49 average peak wattage, 18.80-19.00% efficiency), upon removal of the release liner. The crystalline silicon solar cells contained no silver paste busbars on the aluminum backside, and are also referred to as full-aluminum back plane cells. These cells were obtained from a commercial manufacturer of solar cells and are intended to be identical to commercial solar cells but lacking the customary silver paste busbars on the backside of the solar cell. The three strips of metal tape were 132 mm in length and placed such that their relative location corresponded to the location of three silver busbars disposed on the frontside of the solar cell. The metal tape strips were then bonded to the solar cell with a hot bar bonder (Cherusal, model number TM-100P-0222-LB, manufactured by Trimech Technology PTE LTD, Singapore). The metal hot bar on the hot bar bonder was 6 in (15 cm) long and 3 mm wide. The metal tape was bonded over a 10 second time period using the following time and temperature program: ramp to 350° C. over 1 second, hold at 350° C. for 3 seconds, ramp down to 320° C. over 3 seconds, hold at 320° C. for 1 second, ramp down to 300° C. over 1 second, hold at 300° C. for 1 second. The bonding pressure was held constant at 200 psi during the entire 10 second bonding period. A sheet of 0.185 mm thick silicone rubber interposer (supplied by Trimech Technology PTE LTD, Singapore) was placed between the copper foil tape and the metal hot bar element during bonding.

A two-cell solar module was constructed using two full-aluminum back plane cells with metal tape busbars bonded to the full aluminum backside of the solar cell. The two solar cells were electrically connected in series by manually soldering lead free tabbing ribbon (E. Jordan Brooks CA-110, 96.5% tin/3.5% silver, 0.005 gauge, and 0.080 inch width) to the silver busbars on the frontside of the solar cell and to the bonded metal tape busbars on the backside of the solar cell. The tabbing ribbon was soldered to a cross bus on each side of the two-cell string. An electrical lead was soldered to each cross bus. The two-cell string was laminated using a 7.25 in (18.4 cm) by 14 in (35.5 cm) piece of ⅛ in (0.3 cm) thick solar Solite Solar Glass (manufactured by AFG Industries, Kingsport, Tenn.), “Solar Encapsulant Film EVA9000”, and 3M Scotchshield Film 17T backsheet. The laminator and lamination conditions described for Test Panel 1 were used. Two-cell Modules 1A and 1B were prepared in this manner.

### Comparative Test Panel A

A comparative Test Panel A was prepared as described in Test Panel 1 with the following exceptions: (1) the metal tape used was prepared as described in the Comparative Example A; (2) the hot bar bonder used was model “1093” obtained from Design Concepts Inc, Olathe, Kans. set at a temperature of 325° C.; and (3) the encapsulant used was obtained under the trade designation “LIGHTSWITCH” from Saint-Gobain, Paris, France.

### Comparative Test Panel B

Comparative Test Panel B was prepared as described in Test Panel 1 with the following exceptions: 1) The pressure sensitive foil adhesive tape was bonded to the aluminum backside of a standard crystalline silicon solar cell by laminating at room temperature with a rubber roller using approximately 7 lbs of force. 2) The exposed pressure sensitive adhesive on the tape extending beyond the panel was not removed. 3) The simulated soldering process was not done. 4) “Solar Encapsulant Film EVA9100”, and 3M Scotchshield Film 17T backsheet were used.

### Comparative Test Panel C

Comparative Test Panel C was prepared as described in Comparative Single Cell Module B, except that the tape used was prepared as described in the Comparative Example C.

### Comparative Test Panel D

Comparative Test Panel D was prepared as described in Comparative Single Cell Module B, except that the tape used was prepared as described in the Comparative Example D.

### Comparative Test Panel E

Comparative Test Panel E was prepared as described in Test Panel 1 with the following exceptions. 1) Comparative Example E was bonded with the following conditions: ramp up to 350 C over 1 second, hold at 350 C for 30 seconds. 2) The simulated soldering process was not done. 3) “Solar Encapsulant Film EVA9100”, and 3M Scotchshield Film 17T backsheet were used.

### Comparative Test Panel F

Comparative Test Panel F was prepared as described in Comparative Test Panel E, except that the tape used was prepared as described in Comparative Example F.

### Comparative Test Panel G

Comparative Test Panel G was prepared as described in Test Panel 1 with the following exceptions: 1) The tape used was prepared as described in the Comparative Example G, 2) The simulated soldering process was not done. 3) “Solar Encapsulant Film EVA9100”, and 3M Scotchshield Film 17T backsheet were used.

### Comparative Test Panel H

Comparative Test Panel H was prepared as described in Test Panel 1, with the following exceptions: 1) Comparative Example H was bonded with the following conditions: ramp up to 350 C over 1 second, hold at 350 C for 15 seconds. 2) The simulated soldering process was not done. 3) “Solar Encapsulant Film EVA9100”, and 3M Scotchshield Film 17T backsheet were used.

Resistance of the metal tape strips in the Test Panels 1-3, and Comparative Test Panels A-H was measured before and after aging, using the procedures described above. Results obtained using the first aging test (using a temperature cycle), as described above, are reported in Table 4, below, wherein cells with no data indicate the variable was not measured. Results are expressed as average resistance of three test panels prepared as described in Test Panel 1 and Test Panel 3. For Test Panel 2 and Comparative Test Panel A, resistance is reported as an average of two Test Panels. For Comparative Test Panels B through H, a resistance is reported from a single test panel.

In the data and plots below, the outstanding stability in thermal cycling of the foil adhesive in Example 1 relative to the comparative examples is clear. Furthermore, long term stability of the non-conductive adhesive in both thermal cycling (Test Panel 1) and 85/85 (Test Panel 2) is also demonstrated below.

TABLE 4
Results of First Aging Test Using a Temperature Cycle

| | Resistance (milliohms) | | | | | | | | |
|---|---|---|---|---|---|---|---|---|---|
| | Initial | 24 | 48 | 72 | 144 | 336 | 360 | 384 | 2016 |
| Panels | (0) | hr | hr | hr | hr | hr | hr | hr | hr |
| Test Panel 1 | 4.81 | | | | | | | 4.73 | 4.74 |
| Test Panel2 | 3.82 | | | | | 3.70 | | | 3.62 |
| Test Panel 3 | 4.61 | | | | | | | 4.44 | 4.42 |
| Comp. Test Panel A | 0.15 | | | | | | 0.68 | | |
| Comp. Test Panel B | 0.3 | 1.4 | 5.5 | 9.1 | 25 | | | | |
| Comp. Test Panel C | 3.7 | 4.3 | 28.5 | 156 | | | | | |
| Comp. Test Panel D | 4 | 19.9 | 65.5 | | | | | | |
| Comp. Test Panel E | 7.4 | 378.3 | 325 | | | | | | |
| Comp. Test Panel F | 9.1 | 20 | 60.5 | | | | | | |
| Comp. Test Panel G | 3.9 | 38.7 | 146.5 | | | | | | |
| Comp Test Panel H | 1.1 | 11.1 | 31.3 | | | | | | |

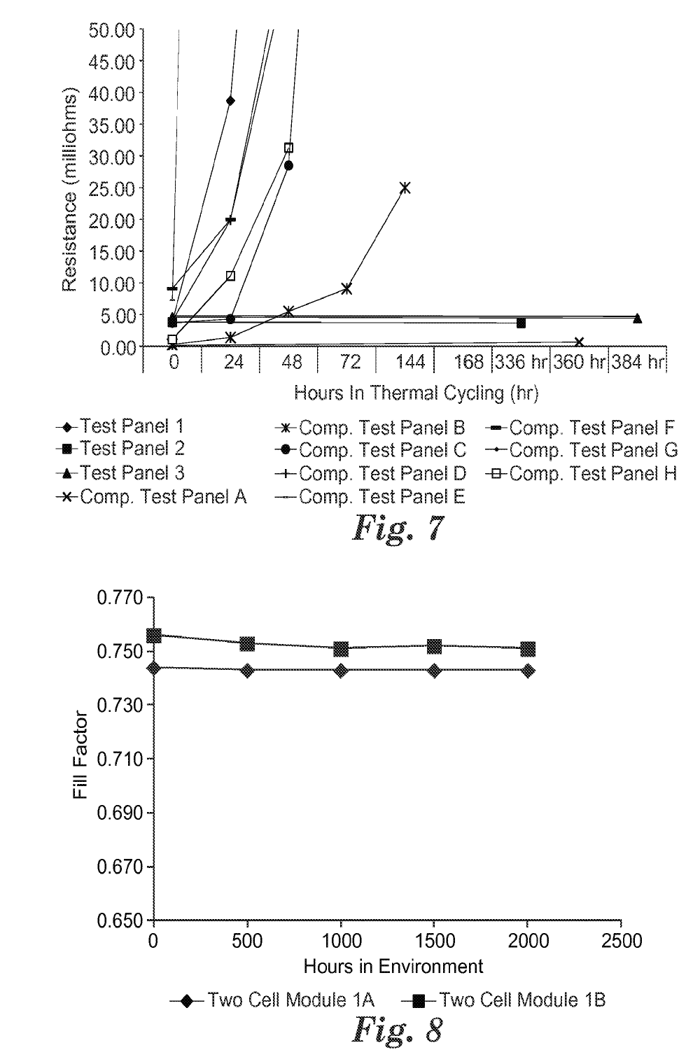

A graphical representation of the first Aging test using a temperature cycle is shown in FIG. 7.

Resistance for modules submitted to the second aging test (85° C./85% Relative Humidity testing), as described above, are reported in Table 5, below. Results are expressed as average resistance of three replicate test panels prepared as described in Test Panel 1, Test Panel 3, and Comparative Test Panel A, as appropriate. Results are expressed as an average resistance from two replicate test panels for Test Panel 2.

TABLE 5
Results of 85° C./85% Relative Humidity Testing

Resistance (milliohms)

| | Initial | 336 | 360 | 384 | 2016 |
|---|---|---|---|---|---|
| Modules | (0) | hr | hr | hr | hr |
| Test Panel 1 | 4.906 | | | 4.527 | 4.346 |
| Test Panel 2 | 3.930 | 3.721 | | | 3.238 |
| Test Panel 3 | 4.465 | | | 3.934 | 3.458 |
| Comp. Test Panel A | 0.259 | | 1.931 | | |

The initial photovoltaic testing data on Two-Cell Modules 1A and 1B is given below in Table 6. The data clearly illustrate that fully functioning photovoltaic modules can be constructed using crystalline silicon solar cells having Example 4 metal tape bonded to a full aluminum backplane.

TABLE 6

| | Two-Cell Module 1A | Two-Cell Module 1B |
|---|---|---|
| Fill Factor | 0.744 | 0.756 |
| Voc | 1.259 V | 1.262 V |
| Isc | 9.244 A | 9.318 A |
| Pmax | 8.661 W | 8.897 W |
| Efficiency | 18.12% | 18.86% |

Two-cell Module 1A was placed in 85 C/85% relative humidity for 1500 hours. Two-cell Module 1B was placed in thermal cycling for 1500 hours/300 thermal cycles. Both Two-cell modules were removed from the respective environments and tested on the photovoltaic module tester after 500 hours of exposure. Photovoltaic module test values (fill factor, Pmax and Efficiency) from each 500 hour test interval are listed below in Table 7.

TABLE 7

| | | | | |
|---|---|---|---|---|
| 0 | 500 | 1000 | 1500 | 2000 |
| hours | hrs | hrs | hrs | hrs |

Fill Factor

| | | | | | |
|---|---|---|---|---|---|
| Two Cell Module 1A | 0.744 | 0.743 | 0.743 | 0.743 | 0.743 |
| (85 C./85RH) | | | | | |
| Two Cell Module 1B | 0.756 | 0.753 | 0.751 | 0.752 | 0.751 |
| (thermal cycling) | | | | | |

Pmax(W)

| | | | | | |
|---|---|---|---|---|---|
| Two Cell Module 1A | 8.661 | 8.622 | 8.644 | 8.603 | 8.606 |
| (85 C./85RH) | | | | | |
| Two Cell Module 1B | 8.897 | 8.869 | 8.851 | 8.841 | 8.874 |
| (thermal cycling) | | | | | |

Efficiency (%)

| | | | | | |
|---|---|---|---|---|---|
| Two Cell Module 1A | 18.119 | 18.037 | 18.084 | 17.999 | 18.004 |
| (85 C./85RH) | | | | | |
| Two Cell Module 1B | 18.614 | 18.554 | 18.517 | 18.495 | 18.564 |
| (thermal cycling) | | | | | |

Fill factor for Two-Cell Module 1A and Two-Cell Module 1B are shown in the plot below in FIG. 8.

In the data shown above, it may be seen the outstanding stability in thermal cycling of the metal tapes prepared in the Examples relative to the Comparative Examples. Furthermore, long term stability of the non-conductive adhesive in both thermal cycling and accelerated aging 85C/85RH conditions is also demonstrated.

### Example 5

A copper foil having a thickness of 12 microns (obtained under the trade designation “TOB-III”, from OakMitsui, Camden, S.C.) was provided. The copper foil had a first surface and a second surface, the first surface coated with a primer comprising a chromium/zinc alloy. A solvent based epoxy thermoset adhesive was prepared using the ingredients listed in Table 8, below, wherein the amount of each ingredient is expressed as weight percent based on the total adhesive weight. The first five ingredients listed in Table 8 below were mixed aggressively with a cowles-type mixer for 1 hour. The second charge of MEK was then added slowly with mixing, and the resulting mixture was gently mixed for 5 minutes. The mixture was subsequently filtered through a 100 micron filter.

TABLE 8
Composition of Solvent Based Epoxy
Thermoset Adhesive of Example 5

| | Trade | | Weight |
|---|---|---|---|
| Ingredient | designation | Supplier | percent (%) |
| Epoxy resin | EPON SU-2.5 | Momentive, | 29.91 |
| | | Columbus | |
| 40% Phenoxy resin | PKHS-40 | InChem | 10.00 |
| in methyl ethyl | | Corporation | |
| ketone | | | |
| Core-shell | PARALOID | Dow Chemical, | 4.00 |
| particles | EXL-2330 | Midland | |
| Epoxy curative | 2MZ-AZINE | Air Products, | 2.09 |
| | (fine grind) | Allentown | |
| Solvent | Methyl ethyl | Brenntag | 6.64 |
| | ketone (MEK) | Great Lakes | |
| | (first charge) | | |
| Solvent | MEK | Brenntag | 47.36 |
| | (second charge) | Great Lakes | |

The adhesive was further filtered through a 30 micron filter and then coated onto the primed side of the 17 inch (43 cm) wide and 12 micron thick copper foil (Oak Mitsui TOB-III). The line speed of the coating process was 60 ft/min. The adhesive layer was dried in a series of drying ovens set, respectively, at 130° F. (54° C.), 150° F. (65° C.), and 170° F. (77° C.). The adhesive-coated foil was subsequently passed through two standard 25 ft (7.6 m) long drying ovens set at 170° F. The dried adhesive layer had a thickness of 20 microns. The release liner (obtained under the trade name “T-50”, from Eastman Chemical Co., Martinsville, Va.) was laminated over the adhesive layer, and the 17 in (43 cm) wide metal tape was slit into two 8 in (20 cm) wide rolls.

The two metal tape rolls were embossed on the copper side with a dot pattern comprised of protrusions arranged in a trapezoidal configuration at a density of 41 protrusions per square centimeter. Each protrusion had a height of about 0.39 mm, and diameters of about 0.74 mm at the base and about 0.43 mm at the top. The embossing process was done on a roll to roll apparatus using an embossing force of 700 lbf (317 kgf), and a line speed of 10 ft/min (3 m/min). In addition, an unwind tension of 5 lbf (2.27 kgf) and a wind tension of 10 lbf (4.5 kgf) were applied. The embossed metal tape was then slit into 3 mm wide rolls.

### Example 6

Embossed metal foil tape was prepared exactly as described in Example 5 with the following exceptions: (1) the adhesive was coated with a dry thickness of 11 microns; (2) the embossing was done at 20 ft/min (6.1 m/min) with an unwind tension of 20 lbf (9.1 kgf).

Two-Cell Module 2

Three strips of the metal tape of Example 5 were applied to an aluminum backside of a crystalline silicon solar cell (4.49 average peak wattage, 18.80-19.00% efficiency), upon removal of the release liner. The crystalline silicon solar cells contained no silver paste busbars on the aluminum backside, and are also referred to as full-aluminum back plane cells. These cells were obtained from a commercial manufacturer of solar cells and are intended to be identical to commercial solar cells but lacking the customary silver paste busbars on the backside of the solar cell. The three strips of metal tape were 132 mm in length and after removal of the release liner, placed such that their relative location corresponded to the location of three silver busbars disposed on the frontside of the solar cell. The metal tape strips were then bonded to the solar cell with a hot bar bonder (Cherusal, model number TM-100P-0222-LB, manufactured by Trimech Technology PTE LTD, Singapore). The metal hot bar on the hot bar bonder was 6 in (15 cm) long and 3 mm wide. The metal tape was bonded over a 10 second time period using the following time and temperature program: ramp to 350° C. over 1 second, hold at 350° C. for 3 seconds, ramp down to 320° C. over 3 seconds, hold at 320° C. for 1 second, ramp down to 300° C. over 1 second, hold at 300° C. for 1 second. The bonding pressure was held constant at 200 psi during the entire 10 second bonding period. A sheet of 0.20 mm thick silicone rubber interposer (obtained under the trade name Sarcon 30T from Fujipoly America Corp., Carteret, N.J.) was placed between the copper foil tape and the metal hot bar element during bonding.

Using the solar cells described above which were bonded with embossed metal tape on the aluminum backside, these same solar cells were bonded on the frontside with metal tape prepared in Example 6 after removal of the release liner. The three strips of metal tape were 132 mm in length and were placed parallel to the three frontside silver busbars (approximately 2 mm offset) such that the metal tape only contacted the fine silver gridlines (or fingers). The three metal tape strips were then bonded to the frontside of the solar cell using exactly the same procedure as described above for bonding metal tape to the aluminum backside of the solar cell.

Two-cell solar modules were constructed using two full-aluminum back plane cells with metal tape busbars bonded to the full aluminum backside of the solar cell, and metal tape busbars bonded to the frontside of the solar cell. The two cells in the two-cell module had to be slightly offset relative to each other to accommodate the offset metal tape busbars on the frontside of each solar cell. The two solar cells were electrically connected in series by manually soldering tabbing ribbon (E. Jordan Brooks CA-110, 60% tin/40% lead, 0.15 mm×2.0 mm) to the bonded metal tape busbars on the frontside of the solar cell and to the bonded metal tape busbars on the backside of the solar cell. A solder flux (GS-3434 obtained from Indium Corporation of America, Utica, N.Y.) was used in the soldering process. The tabbing ribbon was soldered to a cross bus on each side of the two-cell string. An electrical lead was soldered to each cross bus thus creating the solar cell assembly. A two cell module was prepared by placing the following components in a laminator (model “LM-50X50-S”, obtained from NPC, Tokyo, Japan): an ethyl vinyl acetate (EVA) encapsulant (obtained under the trade designation “3M 9100”, from 3M Company, St. Paul, Minn.) was disposed on the front side and rear side of the two cell string, and 7.25 in (18.4 cm) by 14 in (35.5 cm) piece of ⅛ in (0.3 cm) thick solar Solite Solar Glass (manufactured by AFG Industries, Kingsport, Tenn.) was disposed over the EVA encapsulant. A backsheet (obtained from 3M Company under the trade designation “SCOTCHSHIELD FILM 17T”) was disposed adjacent the back side of the solar cell. Lamination of these layers was carried out using the following process conditions: a 4 min pump down at 150° C. (with the pins up) followed by a 12 minute press at 150° C.

The initial photovoltaic testing data on Two-Cell Modules 2A and 2B is given below in Table 9. The data clearly illustrate that fully functioning photovoltaic modules can be constructed using crystalline silicon solar cells having busbars on both the frontside and the rearside constructed from metal tape.

TABLE 9

| | Two-Cell Module 2A | Two-Cell Module 2B |
|---|---|---|
| Fill Factor | 0.751 | 0.759 |
| Voc (V) | 1.259 | 1.267 |
| Isc (A) | 9.059 | 9.076 |
| Pmax (W) | 8.562 | 8.723 |
| Efficiency (%) | 17.911 | 18.250 |

Two-cell Module 2A was placed in 85 C/85% relative humidity for 1000 hours. Two-cell Module 2B was placed in thermal cycling for 2000 hours/400 thermal cycles. Both Two-cell modules were removed from the respective environments and tested on the photovoltaic module tester after 500 hours of exposure. Photovoltaic module test values (fill factor, Pmax and Efficiency) from each 500 hour test interval are listed below in Table 10.

TABLE 10

| | | | | |
|---|---|---|---|---|
| 0 | 500 | 1000 | 1500 | 2000 |
| hours | hrs | hrs | hrs | hrs |

Fill Factor

| | | | | | |
|---|---|---|---|---|---|
| Two Cell Module 2A | 0.751 | 0.756 | 0.754 | 0.755 | 0.753 |
| (85 C./85RH) | | | | | |
| Two Cell Module 2B | 0.759 | 0.755 | 0.752 | 0.748 | 0.743 |
| (thermal cycling) | | | | | |

Pmax(W)

| | | | | | |
|---|---|---|---|---|---|
| Two Cell Module 2A | 8.562 | 8.615 | 8.589 | 8.583 | 8.613 |
| (85 C./85RH) | | | | | |
| Two Cell Module 2B | 8.723 | 8.672 | 8.644 | 8.580 | 8.607 |
| (thermal cycling) | | | | | |

Efficiency (%)

| | | | | | |
|---|---|---|---|---|---|
| Two Cell Module 2A | 17.911 | 18.023 | 17.968 | 17.956 | 18.019 |
| (85 C./85RH) | | | | | |
| Two Cell Module 2B | 18.250 | 18.142 | 18.084 | 17.951 | 18.006 |
| (thermal cycling) | | | | | |

The Fill factor for Two-Cell Module 2A and Two-Cell Module 2B are shown in FIG. 10.

In the data shown above, the outstanding stability in thermal cycling of the metal tape prepared in the Examples is illustrated. Furthermore, long term stability of the non-conductive adhesive in 85C/85RH conditions is also demonstrated. The performance degradation of module 2B is about 2% over 2000 hours in 85/85, and module 2A shows essentially no degradation over 2000 hours (400 thermal cycles). For comparison, the IEC benchmark in such aging tests is less than a 5% drop in performance over 1000 hours. Surprisingly, the data also shows that the performance of the front-side tape is similar to that of the back-side tape given that the substrate to which the front-side tape is bonded is non-porous and different from the aluminum paste to which the back-side tape is bonded.

### Example 7

An acrylic adhesive was prepared by mixing together the ingredients listed in the table 11. Next, the center portion of an approximately 14 inch by 6 inch piece of 35 micron copper foil (obtained under the trade name “ML” from OakMitsui) was embossed with 6 inch by 6 inch dot pattern tool. The embossing was done such that the embossing tool was placed on the shiny side of the copper foil. The dot pattern on the embossing tool comprised protrusions arranged in a trapezoidal configuration at a density of 41 protrusions per square centimeter. Each protrusion had a height of about 0.39 mm, and diameters of about 0.74 mm at the base and about 0.43 mm at the top. The foil and embossing tool was placed in a platen press, and a force of about 20,000 lbs was applied to the embossing tool. Next, using a laboratory handspread coater equipped with a 1.5 mil gap, the acrylic adhesive solution (see the table below) was coated onto the dull side of the embossed portion of the copper foil. The acrylic adhesive solution was dried in an oven at 60 degrees C. for 12 minutes. The acrylic adhesive-coated foil was slit into strips that were 3 mm wide and about 9 inches long such that the 6 inch embossed section of the foil containing the coated adhesive was in the center of the 9 inch long strip.

TABLE 11

| | Trade | | Weight |
|---|---|---|---|
| Ingredient | Designation | Supplier | Percentage (%) |
| Acrylic resin | SR399 | Sartomer | 50.34 |
| Acrylic resin | CN1202 | Sartomer | 21.58 |
| Core Shell | Paraloid | Dow Chemical | 8.20 |
| Particle | EXL-2330 | | |
| Acrylate | Benzoyl | Aldrich | 1.91 |
| curative | peroxide | Chemical | |
| methyl ethyl | solvent | Brenntag | 17.97 |
| ketone | | Great Lakes | |

Test Panels 4, 5, 6 and 7

Test Panels 4, 5, 6 and 7 were prepared using the procedure described in Comparative Test Panel A with the exception that the bonding temperature was set to 255 degrees C. during the entire 10 second bonding time.

Test Panels 4 and 5 were place in thermal cycling, and Test Panels 6 and 7 were placed in 85/85. The resistance data of the Test Panels 4 and 5 in thermal cycling is listed in Table 12, and the resistance data of Test Panels 6 and 7 in 85/85 is listed in Table 13 below.

TABLE 12
Thermal cycling data onTest Panels 4 and 5

| | Resistance (milliohms) | | | | | | | | | |
|---|---|---|---|---|---|---|---|---|---|---|
| | | 72 | 120 | 288 | 456 | 792 | 1128 | 1512 | 2016 | 2520 |
| Panels | initial | hr | hr | hr | hr | hr | hr | hr | hr | hr |
| Test Panel 4 | 1.654 | 1.615 | 1.584 | 1.547 | 1.517 | 1.48 | 1.463 | 1.451 | 1.428 | 1.429 |
| Test Panel 5 | 1.551 | 1.501 | 1.465 | 1.419 | 1.381 | 1.341 | 1.341 | 1.307 | 1.281 | 1.283 |

TABLE 13
85/85data on Test Panels 6 and 7

| | Resistance (milliohms) | | | | | | | | | |
|---|---|---|---|---|---|---|---|---|---|---|
| | | 72 | 120 | 288 | 456 | 792 | 1128 | 1512 | 2016 | 2520 |
| Panels | initial | hr | hr | hr | hr | hr | hr | hr | hr | hr |
| Test Panel 6 | 1.606 | 1.585 | 1.561 | 1.519 | 1.459 | 1.315 | 1.135 | 0.258 | 7.731 | 44.886 |
| Test Panel 7 | 1.646 | 1.624 | 1.599 | 1.571 | 1.524 | 1.434 | 1.357 | 1.066 | 1.161 | 13.733 |

While the specification has described in detail some embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. Furthermore, all publications, published patent applications and issued patents referenced herein are incorporated by reference in their entirety to the same extent as if each individual publication or patent was specifically and individually indicated to be incorporated by reference. Various embodiments have been described. These and other embodiments are within the scope of the following listing of embodiments and claims.

All references mentioned herein are incorporated by reference.

As used herein, the words “on” and “adjacent” cover both a layer being directly on and indirectly on something, with other layers possibly being located therebetween.

As used herein, the terms “major surface” and “major surfaces” refer to the surface(s) with the largest surface area on a three-dimensional shape having three sets of opposing surfaces.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise.

As used in this disclosure and the appended claims, the term “or” is generally employed in its sense including “and/or” unless the content clearly dictates otherwise.

The phrases “at least one of” and “comprises at least one of” followed by a list refers to any one of the items in the list and any combination of two or more items in the list. All numerical ranges are inclusive of their endpoints and non-integral values between the endpoints unless otherwise stated.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this invention is not intended to be unduly limited by the illustrative embodiments and examples set forth herein and that such examples and embodiments are presented by way of example only with the scope of the invention intended to be limited only by the claims set forth herein as follows. Further, various modifications and alterations of the present invention will become apparent to those skilled in the art without departing from the spirit and scope of the present disclosure. The scope of the present application should, therefore, be determined only by the following claims.

### Additional Exemplary Embodiments

A. A busbar tape comprising:
a conductive metal foil; and
a nonconductive thermoset adhesive;
wherein the tape is solderable and
wherein the tape is capable of adhering to a porous nonsolderable aluminum surface.

B. The busbar tape of embodiment A, wherein the busbar tape is embossed.

C. The busbar tape of any of the preceding embodiments, wherein the nonsolderable aluminum surface is the rear aluminum surface of a photovoltaic solar cell.

D. The busbar tape of any of the preceding embodiments, wherein at least some of the nonconductive adhesive is capable of entering the pores of the porous nonsolderable aluminum surface.

E. The busbar tape of any of the preceding embodiments, wherein the metal foil comprises copper, aluminum, tin, iron, nickel, silver, gold, lead, zinc, cobalt, chromium, titanium, and mixtures thereof.

F. The busbar tape of any of the preceding embodiments, wherein the metal foil comprises copper.

G. The busbar tape of any of the preceding embodiments, wherein the metal foil further comprises zinc.

H. The busbar tape of any of the preceding embodiments, wherein the nonconductive adhesive is tacky.

I. The busbar tape of any of the preceding embodiments, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

J. The busbar tape of any of the preceding embodiments, having a room temperature shelf life of at least 3 weeks.

K. The busbar tape of any of the preceding embodiments, wherein, when the busbar tape is applied to the rear aluminum surface of a photovoltaic cell, the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

L. The busbar tape of any of the preceding embodiments, wherein, when the busbar tape is applied to the rear aluminum surface of a photovoltaic cell, the photovoltaic cell is capable of enduring at least 400 cycles of thermal cycling (−40° C. to 90° C.) and damp heat (85° C./85% Relative Humidity testing) for at least 2000 hours with less than 5% increase in resistance of the electrical connection.

M. A photovoltaic solar cell comprising:
a silicon wafer comprising a front surface and a back surface,
a porous nonsolderable aluminum surface adjacent to the back surface of the silicon wafer, and
a busbar tape,
wherein the busbar tape comprises:
   a conductive metal foil; and
   a nonconductive thermoset adhesive;
   wherein the busbar tape is solderable and
wherein the busbar tape is bonded to the porous nonsolderable aluminum surface adjacent to the back surface of the silicon wafer via the nonconductive thermoset adhesive.

N. The photovoltaic solar cell of embodiment M, wherein the busbar tape is embossed prior to bonding to the porous nonsolderable aluminum surface.

O. The photovoltaic solar cell of any of the preceding embodiments directed to photovoltaic solar cells, wherein at least some of the nonconductive adhesive is capable of entering the pores of the porous nonsolderable aluminum surface.

P. The photovoltaic solar cell of any of the preceding embodiments directed to photovoltaic solar cells, wherein the metal foil comprises copper, aluminum, tin, iron, nickel, silver, gold, lead, zinc, cobalt, chromium, titanium, and mixtures thereof.

Q. The photovoltaic solar cell of any of the preceding embodiments directed to photovoltaic solar cells, wherein the metal foil comprises copper.

R. The photovoltaic solar cell of any of the preceding embodiments directed to photovoltaic solar cells, wherein the metal foil is tin coated.

S. The photovoltaic solar cell of any of the preceding embodiments directed to photovoltaic solar cells, wherein the nonconductive adhesive is tacky.

T. The photovoltaic solar cell of any of the preceding embodiments directed to photovoltaic solar cells, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

U. The photovoltaic solar cell of any of the preceding embodiments directed to photovoltaic solar cells, wherein the busbar tape has a shelf life of at least 3 weeks.

V. The photovoltaic solar cell of any of the preceding embodiments directed to photovoltaic solar cells, wherein the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

W. The photovoltaic solar cell of any of the preceding embodiments directed to photovoltaic solar cells, wherein the photovoltaic cell is capable of enduring at least 400 cycles of thermal cycling (−40° C. to 90° C.) and damp heat (85° C./85% Relative Humidity testing) for 2000 hours with less than 5% increase in resistance of the electrical connection.

X. The photovoltaic solar cell of any of the preceding embodiments directed to photovoltaic solar cells, wherein the photovoltaic cell does not include a silver paste on the porous nonsolderable aluminum surface.

Y. A photovoltaic solar module comprising two or more photovoltaic solar cells, wherein at least some of the photovoltaic solar cells comprise:
a silicon wafer comprising a front surface and a back surface,
a porous nonsolderable aluminum surface adjacent to the back surface of the silicon wafer,
at least one front-side busbar and
a back-side busbar tape,
wherein the back-side busbar tape comprises:
   a conductive metal foil; and
   a nonconductive thermoset adhesive;
wherein the back-side busbar tape is bonded to the porous nonsolderable aluminum surface adjacent to the back surface of the silicon wafer via the nonconductive thermoset adhesive, and
wherein at least a first photovoltaic solar cell is electrically connected in series to a second photovoltaic solar cell via a tabbing ribbon,
wherein one end of the tabbing ribbon has been soldered to the front-side busbar of the first photovoltaic solar cell and the other end of the tabbing ribbon has been soldered to the back-side busbar tape of the second photovoltaic solar cell.

Z. The photovoltaic solar module of embodiment Y, wherein the busbar tape is embossed prior to bonding to the porous nonsolderable aluminum surface.

AA. The photovoltaic solar module of any of the preceding embodiments directed to photovoltaic solar modules, wherein at least some of the nonconductive adhesive is capable of entering the pores of the porous nonsolderable aluminum surface.

BB. The photovoltaic solar module of any of the preceding embodiments directed to photovoltaic solar modules, wherein the metal foil comprises copper, aluminum, tin, iron, nickel, silver, gold, lead, zinc, cobalt, chromium, titanium, and mixtures thereof.

CC. The photovoltaic solar module of any of the preceding embodiments directed to photovoltaic solar modules, wherein the metal foil comprises copper.

DD. The photovoltaic solar module of any of the preceding embodiments directed to photovoltaic solar modules, wherein the metal foil is tin coated.

EE. The photovoltaic solar module of any of the preceding embodiments directed to photovoltaic solar modules, wherein the nonconductive adhesive is tacky.

FF. The photovoltaic solar module of any of the preceding embodiments directed to photovoltaic solar modules, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

GG. The photovoltaic solar module of any of the preceding embodiments directed to photovoltaic solar modules, wherein the busbar tape has a room temperature shelf life of at least 3 weeks.

HH. The photovoltaic solar module of any of the preceding embodiments directed to photovoltaic solar modules, wherein the photovoltaic module is capable of enduring at least 200 cycles of thermal cycling (−40° C. to 90° C.) and damp heat (85° C./85% Relative Humidity testing) for at least 1000 hours with less than 5% increase in resistance of the electrical connection.

II. The photovoltaic solar module of any of the preceding embodiments directed to photovoltaic solar cells, wherein the photovoltaic module is capable of enduring at least 400 cycles of thermal cycling (−40° C. to 90° C.) and damp heat (85° C./85% Relative Humidity testing) for 2000 hours with less than 5% increase in resistance of the electrical connection.

JJ. The photovoltaic solar module of any of the preceding embodiments directed to photovoltaic solar cells, wherein at least some of the photovoltaic cells do not include a silver paste on the porous nonsolderable aluminum surface.

KK. A method of providing a solderable surface on a photovoltaic solar cell,
wherein the photovoltaic solar cell comprises:
   a silicon wafer comprising a front surface and a back surface,
   a porous nonsolderable aluminum surface adjacent to the back surface of the silicon wafer, and
   a busbar tape,
   wherein the busbar tape comprises:
      a conductive metal foil; and
      a nonconductive thermoset adhesive;
      wherein the busbar tape is solderable and
the method comprising:
applying the busbar tape to the porous nonsolderable aluminum surface of photovoltaic solar cell, and
hot pressing the busbar tape and the photovoltaic solar cell.

LL. The method of embodiment KK, wherein the busbar tape is embossed prior to bonding to the porous nonsolderable aluminum surface.

MM. The method of any of the preceding embodiments directed to methods, wherein at least some of the nonconductive adhesive is capable of entering the pores of the porous nonsolderable aluminum surface.

NN. The method of any of the preceding embodiments directed to methods, wherein the metal foil comprises copper, aluminum, tin, iron, nickel, silver, gold, lead, zinc, cobalt, chromium, titanium, and mixtures thereof.

OO. The method of any of the preceding embodiments directed to methods, wherein the metal foil comprises copper.

PP. The method of any of the preceding embodiments directed to methods, wherein the metal foil is tin coated.

QQ. The method of any of the preceding embodiments directed to methods, wherein the nonconductive adhesive is tacky.

RR. The method of any of the preceding embodiments directed to methods, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

SS. The method of any of the preceding embodiments directed to methods, wherein the busbar tape has a room temperature shelf life of at least 3 weeks.

TT. The method of any of the preceding embodiments directed to methods,
a. wherein the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

UU. The method of any of the preceding embodiments directed to methods,
a. wherein the photovoltaic cell is capable of enduring at least 400 cycles of thermal cycling (−40° C. to 90° C.) and damp heat (85° C./85% Relative Humidity testing) for 2000 hours with less than 5% increase in resistance of the electrical connection.

VV. The method of any of the preceding embodiments directed to methods, wherein the photovoltaic cell does not include a silver paste on the porous nonsolderable aluminum surface.

WW. The method according to any of the preceding embodiments directed to methods, wherein the time during the hot-pressing step is of about 20 seconds or less.

a) A busbar tape comprising:
a. a conductive metal foil; and
b. a nonconductive thermoset adhesive;
c. wherein the tape is solderable and
d. wherein the tape is capable of adhering to crystal-silicon photovoltaic material.

b) The busbar tape of embodiment a), wherein the busbar tape is not embossed.

c) The busbar tape of any of the preceding embodiments, wherein the tape is flexible enough to be able to conform to one or more of the silver gridlines on the front side of a photovoltaic cell.

d) The busbar tape of any of the preceding embodiments, wherein the tape is capable of making an electrical connection with one or more of the silver gridlines on the front side of a photovoltaic cell.

e) The busbar tape of any of the preceding embodiments, wherein the metal foil comprises one or more metals chosen from copper, aluminum, tin, iron, nickel, silver, gold, lead, zinc, cobalt, chromium, titanium, and mixtures thereof.

f) The busbar tape of any of the preceding embodiments, wherein the metal foil comprises copper.

g) The busbar tape of any of the preceding embodiments, wherein the metal foil further comprises zinc.

h) The busbar tape of any of the preceding embodiments, wherein the nonconductive adhesive is tacky.

i) The busbar tape of any of the preceding embodiments, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

j) The busbar tape of any of the preceding embodiments, having a room temperature shelf life of at least 3 weeks.

k) The busbar tape of any of the preceding embodiments, wherein, when the busbar tape is applied to the front side of a photovoltaic cell, the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

l) The busbar tape of any of the preceding embodiments, wherein, when the busbar tape is applied to the front side of a photovoltaic cell, the photovoltaic cell is capable of enduring at least 400 cycles of thermal cycling (−40° C. to 90° C.) and damp heat (85° C./85% Relative Humidity testing) for at least 2000 hours with less than 5% increase in resistance of the electrical connection.

m) A photovoltaic solar cell comprising:
a. a silicon wafer comprising a front surface and a back surface,
b. a busbar tape,
c. wherein the silicon wafer comprises one or more of silver gridlines on the front surface,
d. wherein the busbar tape comprises:
   i. a conductive metal foil; and
   ii. a nonconductive thermoset adhesive;
   iii. wherein the busbar tape is solderable and
e. wherein the busbar tape is bonded to the front surface of the silicon wafer via the nonconductive thermoset adhesive.

n) The photovoltaic solar cell of embodiment m), wherein the busbar tape is not embossed prior to bonding to the front surface of the silicon wafer.

o) The photovoltaic solar cell of any of the preceding embodiments directed to photovoltaic solar cells, wherein the busbar tape is flexible enough to be able to conform to one or more of the silver gridlines on the front surface.

p) The photovoltaic solar cell of any of the preceding embodiments directed to photovoltaic solar cells, wherein the busbar tape is capable of making an electrical connection with one or more of the silver gridlines on the front side of a photovoltaic cell.

q) The photovoltaic solar cell of any of the preceding embodiments directed to photovoltaic solar cells, wherein the metal foil comprises one or more metals chosen from copper, aluminum, tin, iron, nickel, silver, gold, lead, zinc, cobalt, chromium, titanium, and mixtures thereof.

r) The photovoltaic solar cell of any of the preceding embodiments directed to photovoltaic solar cells, wherein the metal foil comprises copper.

s) The photovoltaic solar cell of any of the preceding embodiments directed to photovoltaic solar cells, wherein the metal foil is tin coated.

t) The photovoltaic solar cell of any of the preceding embodiments directed to photovoltaic solar cells, wherein the nonconductive adhesive is tacky.

u) The photovoltaic solar cell of any of the preceding embodiments directed to photovoltaic solar cells, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

v) The photovoltaic solar cell of any of the preceding embodiments directed to photovoltaic solar cells, wherein the busbar tape has a shelf life of at least 3 weeks.

w) The photovoltaic solar cell of any of the preceding embodiments directed to photovoltaic solar cells, wherein the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

x) The photovoltaic solar cell of any of the preceding embodiments directed to photovoltaic solar cells, wherein the photovoltaic cell is capable of enduring at least 400 cycles of thermal cycling (−40° C. to 90° C.) and damp heat (85° C./85% Relative Humidity testing) for 2000 hours with less than 5% increase in resistance of the electrical connection.

y) A photovoltaic solar module comprising two or more photovoltaic solar cells, wherein at least some of the photovoltaic solar cells comprise:
a. a silicon wafer comprising a front surface and a back surface,
b. at least one front-side busbar and
c. at least one back-side busbar tape,
d. wherein the silicon wafer comprises one or more of silver gridlines on the front surface,
e. wherein the front-side busbar tape comprises:
   i. a conductive metal foil; and
   ii. a nonconductive thermoset adhesive;
f. wherein the front-side busbar tape is bonded to the front surface of the silicon wafer via the nonconductive thermoset adhesive, and
g. wherein at least a first photovoltaic solar cell is electrically connected in series to a second photovoltaic solar cell via at least one tabbing ribbon,
h. wherein one end of the at least one tabbing ribbon has been soldered to the at least one front-side busbar of the first photovoltaic solar cell and the other end of the tabbing ribbon has been soldered to the at least one back-side busbar tape of the second photovoltaic solar cell.

z) The photovoltaic solar module of embodiment y), wherein the busbar tape is not embossed prior to bonding to the front surface of the silicon wafer.

aa) The photovoltaic solar module of any of the preceding embodiments directed to photovoltaic solar modules, wherein the busbar tape is flexible enough to be able to conform to one or more of the silver gridlines on the front surface.

bb) The photovoltaic solar module of any of the preceding embodiments directed to photovoltaic solar modules, wherein the busbar tape is capable of making an electrical connection with one or more of the silver gridlines on the front side of a photovoltaic cell.

cc) The photovoltaic solar module of any of the preceding embodiments directed to photovoltaic solar modules, wherein the metal foil comprises one or more metals chosen from copper, aluminum, tin, iron, nickel, silver, gold, lead, zinc, cobalt, chromium, titanium, and mixtures thereof.

dd) The photovoltaic solar module of any of the preceding embodiments directed to photovoltaic solar modules, wherein the metal foil comprises copper.

ee) The photovoltaic solar module of any of the preceding embodiments directed to photovoltaic solar modules, wherein the metal foil is tin coated.

ff) The photovoltaic solar module of any of the preceding embodiments directed to photovoltaic solar modules, wherein the nonconductive adhesive is tacky.

gg) The photovoltaic solar module of any of the preceding embodiments directed to photovoltaic solar modules, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

hh) The photovoltaic solar module of any of the preceding embodiments directed to photovoltaic solar modules, wherein the busbar tape has a room temperature shelf life of at least 3 weeks.

ii) The photovoltaic solar module of any of the preceding embodiments directed to photovoltaic solar modules, wherein the photovoltaic module is capable of enduring at least 200 cycles of thermal cycling (−40° C. to 90° C.) and damp heat (85° C./85% Relative Humidity testing) for at least 1000 hours with less than 5% increase in resistance of the electrical connection.

jj) The photovoltaic solar module of any of the preceding embodiments directed to photovoltaic solar cells, wherein the photovoltaic module is capable of enduring at least 400 cycles of thermal cycling (−40° C. to 90° C.) and damp heat (85° C./85% Relative Humidity testing) for 2000 hours with less than 5% increase in resistance of the electrical connection.

kk) A method of providing a solderable surface on a photovoltaic solar cell,
a. wherein the photovoltaic solar cell comprises:
   i. a silicon wafer comprising a front surface and a back surface, and
   ii. a busbar tape,
   iii. wherein the silicon wafer comprises one or more of silver gridlines on the front surface wherein the busbar tape comprises:
      1. a conductive metal foil; and
      2. a nonconductive thermoset adhesive;
      3. wherein the busbar tape is solderable, and
   b. the method comprising:
   c. applying the busbar tape to the front surface of the silicon wafer of photovoltaic solar cell, and
   d. hot pressing the busbar tape and the photovoltaic solar cell.

ll) The method of embodiment kk), wherein the busbar tape is not embossed prior to bonding to the front surface of the silicon wafer.

mm) The method of any of the preceding embodiments directed to methods, wherein the busbar tape is flexible enough to be able to conform to one or more of the silver gridlines on the front surface.

nn) The photovoltaic solar module of any of the preceding embodiments directed to photovoltaic solar modules, wherein the busbar tape is capable of making an electrical connection with one or more of the silver gridlines on the front side of a photovoltaic cell.

oo) The method of any of the preceding embodiments directed to methods, wherein the metal foil comprises one or more metals chosen from copper, aluminum, tin, iron, nickel, silver, gold, lead, zinc, cobalt, chromium, titanium, and mixtures thereof.

pp) The method of any of the preceding embodiments directed to methods, wherein the metal foil comprises copper.

qq) The method of any of the preceding embodiments directed to methods, wherein the metal foil is tin coated.

rr) The method of any of the preceding embodiments directed to methods, wherein the nonconductive adhesive is tacky.

ss) The method of any of the preceding embodiments directed to methods, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

tt) The method of any of the preceding embodiments directed to methods, wherein the busbar tape has a room temperature shelf life of at least 3 weeks.

uu) The method of any of the preceding embodiments directed to methods,
a. wherein the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

vv) The method of any of the preceding embodiments directed to methods,
a. wherein the photovoltaic cell is capable of enduring at least 400 cycles of thermal cycling (−40° C. to 90° C.) and damp heat (85° C./85% Relative Humidity testing) for 2000 hours with less than 5% increase in resistance of the electrical connection.

ww) The method according to any of the preceding embodiments directed to methods, wherein the time during the hot-pressing step is about 20 seconds or less.

1. A busbar tape comprising:
a conductive metal foil; and
a nonconductive thermoset adhesive;
wherein the tape is solderable and
wherein the tape is capable of adhering to a porous nonsolderable aluminum surface.

2. The busbar tape of claim 1, wherein the busbar tape is embossed.

3. The busbar tape of claim 1, wherein the nonsolderable aluminum surface is the rear aluminum surface of a photovoltaic solar cell.

4. The busbar tape of claim 1, wherein the metal foil comprises one or more metals chosen from copper, aluminum, tin, iron, nickel, silver, gold, lead, zinc, cobalt, chromium, titanium, and mixtures thereof.

5. The busbar tape of claim 1, wherein the metal foil comprises copper.

6. The busbar tape of claim 1, wherein the metal foil further comprises zinc.

7. The busbar tape of claim 1, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

8. The busbar tape of claim 1, wherein, when the busbar tape is applied to the rear aluminum surface of a photovoltaic cell, the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

9. The busbar tape of claim 1, wherein, when the busbar tape is applied to the rear aluminum surface of a photovoltaic cell, the photovoltaic cell is capable of enduring at least 400 cycles of thermal cycling (−40° C. to 90° C.) and damp heat (85° C./85% Relative Humidity testing) for at least 2000 hours with less than 5% increase in resistance of the electrical connection.

10. A photovoltaic solar cell comprising:
the busbar tape of claim 1,
a silicon wafer comprising a front surface and a back surface,
a porous nonsolderable aluminum surface adjacent to the back surface of the silicon wafer, and
a busbar tape,
wherein the busbar tape is bonded to the porous nonsolderable aluminum surface adjacent to the back surface of the silicon wafer via the nonconductive thermoset adhesive.

11. A photovoltaic solar module comprising two or more photovoltaic solar cells, wherein at least some of the photovoltaic solar cells comprise:
a silicon wafer comprising a front surface and a back surface,
a porous nonsolderable aluminum surface adjacent to the back surface of the silicon wafer,
at least one front-side busbar and
at least one busbar tape according to claim 1,
wherein the at least one busbar tape is bonded to the porous nonsolderable aluminum surface adjacent to the back surface of the silicon wafer via the nonconductive thermoset adhesive, and
wherein at least a first photovoltaic solar cell is electrically connected in series to a second photovoltaic solar cell via at least one tabbing ribbon,
wherein one end of the at least one tabbing ribbon has been soldered to the at least one front-side busbar of the first photovoltaic solar cell and the other end of the tabbing ribbon has been soldered to the at least one back-side busbar tape of the second photovoltaic solar cell.

12. A method of providing a solderable surface on a photovoltaic solar cell,
wherein the photovoltaic solar cell comprises:
a silicon wafer comprising a front surface and a back surface,
a porous nonsolderable aluminum surface adjacent to the back surface of the silicon wafer, and
a busbar tape,
wherein the busbar tape comprises:
a conductive metal foil; and
a nonconductive thermoset adhesive;
wherein the busbar tape is solderable and
the method comprising:
applying the busbar tape to the porous nonsolderable aluminum surface of photovoltaic solar cell, and
hot pressing the busbar tape and the photovoltaic solar cell.

13. The method of claim 0, wherein the busbar tape is embossed prior to bonding to the porous nonsolderable aluminum surface.

14. The method of claim 12, wherein the metal foil comprises one or more metals chosen from copper, aluminum, tin, iron, nickel, silver, gold, lead, zinc, cobalt, chromium, titanium, and mixtures thereof.

15. The method of claim 12, wherein the metal foil comprises copper.

16. The method of claim 12, wherein the metal foil is tin coated.

17. The method of claim 12, wherein the nonconductive adhesive comprises at least one of epoxy resins, acrylic resins, polyurethanes, polyesters, polyimides, polyamides, cyanate esters, phenolic resins, maleimide resins, phenoxy resins and mixtures thereof.

18. The method of claim 12, wherein the photovoltaic cell is capable of enduring at least 200 cycles of thermal cycling (−40° C. to 90° C.) and damp heat (85° C./85% Relative Humidity testing) for at least 1000 hours with less than 5% increase in resistance of the electrical connection.

19. The method of claim 12, wherein the photovoltaic cell is capable of enduring at least 400 cycles of thermal cycling (−40° C. to 90° C.) and damp heat (85° C./85% Relative Humidity testing) for 2000 hours with less than 5% increase in resistance of the electrical connection.

20. The method according to claim 12, wherein the time during the hot-pressing step is about 20 seconds or less.
